(19) United States
(12) Patent Application Publication
(10) Pub. No.: US 2009/0283135 A1
(43) Pub. Date: Nov. 19, 2009

(54) APPARATUS COMPRISING LOW VOLTAGE POWER SOURCE

(75) Inventors: Taco Wijnand Neeb, Almere (NL); Ramon Phillippe Van Der Hilst, Amsterdam Zuidoost (NL)

Correspondence Address: HOWREY LLP-EU, C/O IP DOCKETING DEPARTMENT, 2941 FAIRVIEW PARK DR., SUITE 200, FALLS CHURCH, VA, 22042, US

(73) Assignee: TENDRIS SOLUTIONS B.V., NAARDEN (NL)

(21) Appl. No.: 12/511,217

(22) Filed: Jul. 29, 2009

Related U.S. Application Data
(63) Continuation of application No. PCT/EP2008/051066, filed on Jan. 29, 2008.

(30) Foreign Application Priority Data
Jan. 29, 2007 (EP) 07101312.2

(51) Int. Cl. H01L 31/052; H01L 31/042

(52) U.S. Cl. 136/246; 136/244

(57) ABSTRACT

An apparatus is disclosed for powering an electric load with a low-voltage power supply. The apparatus permits the use of low-voltage power cells that are connected predominantly in parallel. The parallel arrangement of the power cells offers significant practical advantages.

In a preferred embodiment the low voltage power cells are photovoltaic cells.

This application is a continuation of international application no. PCT/EP2008/051066, filed on Jan. 29, 2008, and claims priority from European patent application number 07101312.2 filed on Jan. 29, 2007. The contents of these application are hereby incorporated by reference in their entirety.

### BACKGROUND OF THE INVENTION

1. Field of the Invention

The present intention relates to an apparatus for powering an electric load with a low voltage power source. More specifically, the present intention relates to powering an electric load with a power source that generates a voltage that is much lower than the voltage required by electric load. The apparatus increases the voltage to the work point of the electric load, without significant losses in electrical energy.

2. Description of the Related Art

Due to the high cost of fossil fuel and the concern about global warming caused by the production of carbon dioxide in the combustion of fossil fuels, there is a growing interest in power sources that operate on renewable energy. Examples include photovoltaic cells, thermovoltaic cells, hydrogen fuel cells, biofuels cells, and the like.

Many of these power sources produce electrical power at a low voltage, often on the order of one Volt or less. Photovoltaic cells for example provide a voltage of 0.35 to 0.65 V, typically about 0.45 V. For most applications, the electrical power needs to be provided at a much higher voltage, for example 12V direct current, or 110 or 230 volts AC. One reason is that, for a certain amount of electrical energy, the current is inversely related to the voltage, making it impractical to transport low voltage electrical energy over long distances. The high current requires very thick cables, and is associated with a high risk of overheating and fire.

It is therefore customary to provide an assembly in which a significant number of low voltage power sources are connected in series, so as to provide a suitably higher voltage at the terminals of the assembly. For a plurality of low voltage power sources connected in series, the performance of the assembly is governed by the weakest link in the chain. Such an assembly will only optimally perform if all of the individual units provide identical performance. In practice, this is never the case. For example, the performance of enzymes in a biofuel cell differs from cells to cell. Photovoltaic cells in an assembly may differ in electric output. A manufacturing tolerance of 5% is common, which means that even cells receiving identical amounts of solar radiation may have different outputs of electric energy. In addition, cells within an assembly may receive different amounts of solar radiation, for example as result of a shadow or debris covering some of the cells. Such events may reduce the output of an assembly of photovoltaic cells connected in series by 30 to 70%. To some extent this loss may be reduced by incorporating bypass diodes, so that poorly performing cells may be bypassed.

For this reason, there are always weaker cells in an assembly of cells connected in series. These weaker cells drag down the performance of the assembly, because they act as loads on the system rather than as contributors to its performance.

It is an object of the present intention to raise the voltage of a low voltage power source to the required voltage of an electric load without the disadvantages of existing systems.

### SUMMARY OF THE INVENTION

The present intention relates to an apparatus for powering an electric load with a low voltage power source, said apparatus comprising:
a) a low-voltage power source providing an output voltage Vp;
b) a first accumulator of electric energy, connected in series with the low-voltage power source and operating at a first voltage V1;
c) a second accumulator of electric energy, connected in parallel to the first accumulator, and operating at a second voltage V2;

wherein V1+Vp=V2.

Examples of the low voltage power source include photovoltaic cells, thermovoltaic cells, hydrogen fuel cells and biofuel cells.

Examples of accumulators of electric energy for use in the apparatus of the present intention include flywheels, capacitors, and chemical batteries.

### BRIEF DESCRIPTION OF THE DRAWINGS

FIG. 1 presents a diagrammatic representation of a first embodiment of the apparatus of the present invention.

FIG. 2 presents a diagrammatic representation of a second embodiment of the apparatus of the present invention.

FIG. 3 presents a diagrammatic representation of a third embodiment of the apparatus of the present invention.

FIG. 4 presents a diagrammatic representation of a fourth embodiment of the present invention, combining features of the second and third embodiments.

FIG. 5 presents a diagrammatic representation of a fifth embodiment of the apparatus of the present invention.

### DESCRIPTION OF ILLUSTRATIVE EMBODIMENTS

The present intention relates to an apparatus for powering an electric load with a low-voltage power source, said apparatus comprising:
a) a low-voltage power source providing an output voltage Vp;
b) a first accumulator of electric energy, connected in series with the low-voltage power source and operating at a first voltage V1;
c) a second accumulator of electric energy, connected in parallel to the first accumulator, and operating at a second voltage V2;
   wherein V1+Vp=V2.

The low voltage power source for use in the apparatus of the present intention may be any power source producing a voltage Vp that is lower than the voltage required to power the electric load. The low voltage power source may be powered by a fossil fuel, or by a non-fossil fuel, preferably by a renewable energy source. Preferred examples include photovoltaic cells, thermovoltaic cells, hydrogen fuel cells, and biofuel cells.

The invention will be further illustrated for embodiments of the apparatus in which the low voltage power source comprises at least one photovoltaic cell. It will be understood that the principles illustrated by these embodiments can be applied to any other low voltage power source.

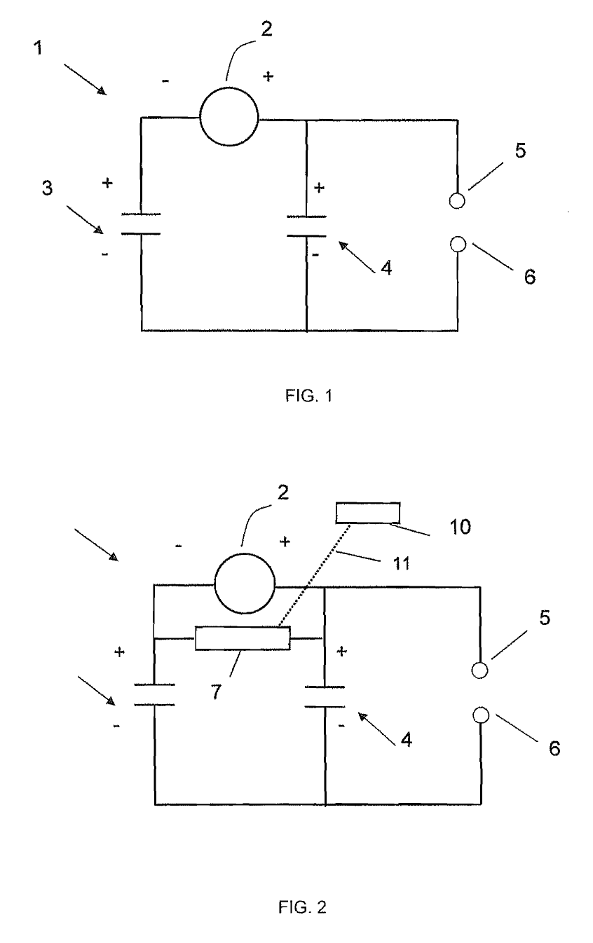

Shown in FIG. 1 is a first embodiment of an apparatus 1, comprising a photovoltaic power source 2. The photovoltaic power source 2 may consist of a single photovoltaic cell, or of a plurality of photovoltaic cells. In the case that photovoltaic power source 2 consists of a plurality of photovoltaic cells, the individual cells may be connected in series, or in parallel, or may consist of a number m of subassemblies of photovoltaic cells, each subassembly containing n photovoltaic cells connected in series. In practice, n is an integer ranging from 1 to 20, preferably from 1 to 10 and more preferably from 1 to 5. The value of the integer m is determined by the selection of the value of n, and the number of photovoltaic cells that the assembly is able to accommodate. The total number of photovoltaic cells is n×m.

Photovoltaic power source 2 is connected in series with a first accumulator of electric energy 3. The second accumulator of electric energy 4 is connected parallel to the first accumulator of electric energy 3. Preferably, the first accumulator 3 and the second accumulator 4 are of equal design, but it will be understood that the apparatus will function properly if the two accumulators are of different design.

The first accumulator 3 provides a first voltage V1. The photovoltaic power source 2 provides an output voltage Vp. The voltage over the second accumulator 4 is given by the equation:

V2=V1+Vp (1)

It will be understood that in practice the value of V2 may be slightly lower than the value provided by equation (1), due to losses in the circuit, in particular when further components are added to the circuit as exemplified in embodiments discussed herein below.

Terminals 5 and 6 are provided for connecting an external electric load, which is to be powered by apparatus 1. When no external load is connected to terminals 5 and 6, electric power generated by photovoltaic power source 2 is used to charge the second accumulator 4. When a load is connected to terminals 5 and 6 that draws less power than is generated by power source 2, any excess power is used to charge accumulator 4. When the external load connected to terminals 5 and 6 consumes more power than is being generated by power source 2, additional power is provided to the load by accumulator 4.

The accumulators to 3 and 4 may be any type of device capable of storing electrical energy. Examples include traditional forms, such as batteries and capacitors, and non-traditional forms such as flywheels provided with electrical generators.

The term “battery” as used herein means a device capable of converting electrical energy into chemical energy, and of converting chemical energy to electrical energy. This type of battery is also referred to as secondary battery or rechargeable battery. Examples include lead-acid batteries, for example wet batteries, gel batteries and absorbent glass mat batteries; lithium ion batteries; lithium ion polymer batteries; NaS batteries; nickel-iron batteries; nickel-metal hydride batteries; nickel-cadmium batteries; nickel-zinc batteries; and molten salt batteries.

Examples of capacitors that may be used as accumulators of electric energy include conventional capacitors (metal film capacitors; mica capacitors; paper capacitors; glass capacitors; and ceramic capacitors); electrolytic capacitors; and in particular the so-called super capacitors.

Super capacitors, sometimes also referred to as ultra capacitors, may be made from carbon aerogel, carbon nano-tubes, or highly porous electrode materials. They are known for their extremely high capacity, and are being evaluated as alternatives to rechargeable batteries. Particularly preferred are ceramic ultra capacitors with a barium-titanate dielectric, which have a high specific energy.

FIG. 2 depicts a diagrammatic representation of a second embodiment of the apparatus of the present invention. This embodiment differs from the embodiment of FIG. 1 by the presence of controller 7. The role of controller 7 is to monitor the output of power source 2, and to optimize its performance. Controller 7 may monitor the performance of power source 2 directly, for example by monitoring the voltage supplied by power source 2 in function of the current in the system. Controller 7 may also monitor external parameters that influence the performance of power source 2. This is illustrated by light detection element 10, which is placed in close proximity of photovoltaic power source 2. Light detection element 10 is connected to controller 7 via connection 11. Connection 11 may be a wire connection, or the communication from detection element 10 to controller 7 may be wireless, such as by an infrared or radio frequency signal. For such indirect monitoring, controller 7 may be provided with a memory device containing data correlating the performance of power source 2 with the value of the parameter measured by detection element 10. For example, controller 7 may use historic data to calculate the power output of power source 2 in function of the light intensity detected by detection element 10.

In a preferred embodiment controller 7 is capable of monitoring and controlling the respective charge conditions of accumulators 3 and 4. For example, if accumulator 4 is fully charged, and power source 2 produces more power than is required by a load connected to terminals 5 and 6, controller 7 will divert electric energy to charge accumulator 3.

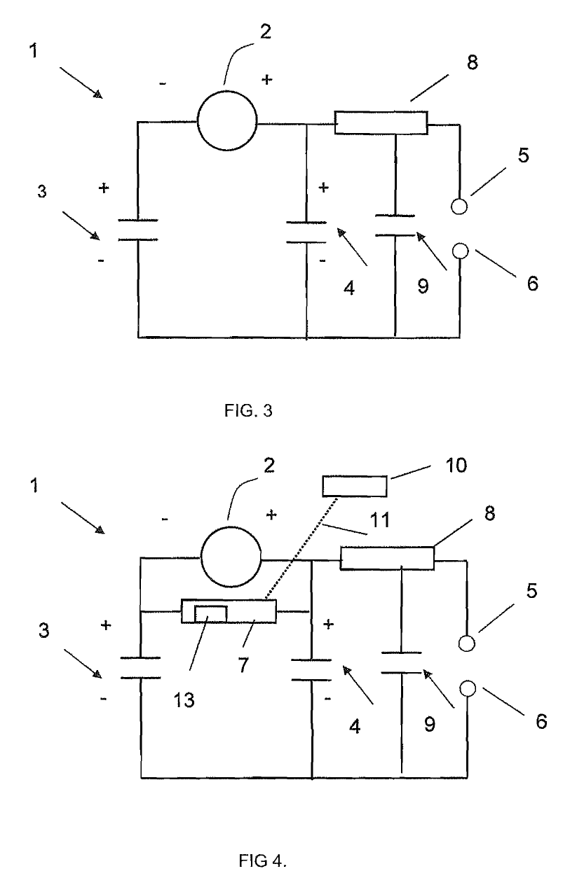

FIG. 3 represents a diagram of a third embodiment of the apparatus of the present invention. In this embodiment a third accumulator of electric energy 9 is included in the apparatus. The nature and design of accumulator 9 may be the same or different from the nature and design of accumulators 3 and 4. For example, accumulators 3 and 4 may be rechargeable batteries, whereas accumulator 9 may be a capacitor. Controller 8 monitors the power production by power source 2, and compares it to the demand of any load connected to terminals 5 and 6. When power source 2 produces more electric energy than is required by the load, controller 8 diverts excess electric energy to accumulator 9.

When the demand of a load connected to terminals 5 and 6 exceeds the power production of power source 2, controller 8 may draw power from accumulator 9. This embodiment is particularly suitable for supplying power to a load having rapidly fluctuating power needs. Rapid changes in power needs can be accommodated by accumulator 9, in particular if actuator 9 is a capacitor. Accumulators 3 and 4, which may be chemical batteries, are more suitable for responding to fluctuations in power needs that are longer lasting.

The embodiment of FIG. 4 combines the features of FIGS. 2 and 3. In addition, controller 7 is equipped with a startup circuit 13. Startup circuit 13 is designed to create and maintain a predetermined minimum charge in accumulators 3 and 4. Specifically, if for some reason the charge values of accumulators 3 and 4 drop below a predetermined minimum value, startup circuit 13 will use power from power source 2 to restore these charges to the required minimum values before power is provided to terminals 5 and 6.

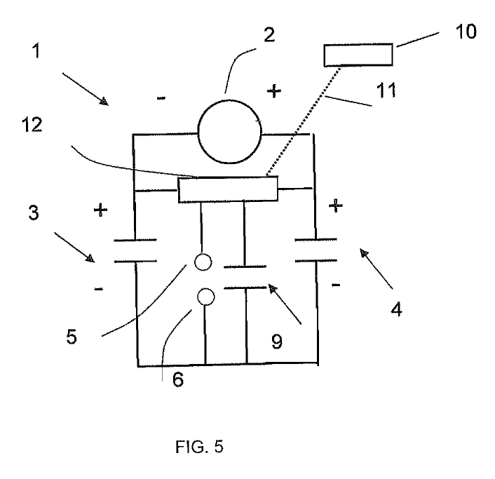

The embodiment of FIG. 5 is similar to the embodiment of FIG. 4. The controllers 7 and 8 of FIG. 4 have been integrated into controller 12 which monitors the operation of power source 2, the charge position of accumulators 3 and 4, the diversion of power to accumulator 9, and the voltage supplied to terminals 5 and 6. Depicted also is external detection element 10, which provides input to controller 12 via connection 11. Connection 11 may be a wire, or it may be wireless connection, such as an infrared or radio signal.

It will be clear from the foregoing that the apparatus of the present invention is capable of providing a voltage to and electric load that is much higher than the voltage generated by the low voltage power source. For this reason, it is not necessary for the low voltage power source to be connected to other such power sources in series. In a preferred embodiment, the apparatus comprises a plurality of photovoltaic cells grouped in a matrix of parallel connected units. Photovoltaic cells may conveniently be connected in parallel by mounting the cells on a unitary sheet of conducting material. Preferably the unitary sheet of conducting material is made of a metal. Preferred metals are those that have a high conductivity for both electricity and heat, and are suitably corrosion resistant. Examples of suitable metals include copper, nickel, aluminum, gold, and alloys thereof. Although gold is preferred in terms of conductivity and corrosion resistance, its price is prohibitive for many applications. Therefore in many cases copper is the preferred metal for use in the unitary sheet.

Mounting photovoltaic cells conductively onto a unitary metal sheet offers a number of advantages. First of all, it obviates the need for wire connections between the corresponding electrodes of the individual photovoltaic cells, which reduces the complexity and cost of the manufacture of a photovoltaic cell assembly. In addition, because the cells are connected in parallel, there is no need for bypass diodes as are often included in photovoltaic cell grids that have the cells connected in series. Yet another advantage is improved dissipation of heat through the unitary sheet of conducting material. In use, photovoltaic cells generate heat as a byproduct. This is undesirable, because the effectiveness of photovoltaic cells goes down as the temperature of the cells goes up. Having the cells mounted on a metal sheet makes it possible to provide cooling by thermally connecting the conducting material to a cooling medium. This may conveniently be accomplished by providing a cooling coil to the surface of the sheet opposite to the surface to which the photovoltaic cells are mounted. The cooling coil may be connected to a heat pump, so that the temperature of the photovoltaic cells may be kept at or near its optimum. The heat energy may be recovered from the cooling medium and may be used for heating purposes, for example for heating a water supply.

As mentioned hereinabove, it is advantageous to maximize the number of photovoltaic cells that are connected in parallel, and minimize same the number of photovoltaic cells that are connected in series. This reduces the need for bypass diodes. Accordingly, the low voltage power source preferably contains fewer than two bypass diodes for every 10 photovoltaic cells present in the low voltage power source, and preferably the low voltage power source is free of bypass diodes.

Another advantage of connecting the photovoltaic cells in parallel is that a small number of photovoltaic cells, each having a large surface area, may be used. In a preferred embodiment, the apparatus comprises a low voltage power source which comprises at least one photovoltaic cell having the surface area of more than 400 square cm, preferably more than 600 square cm, still more preferably more than 1,000 square cm.

As mentioned earlier, it is not necessary for the low-voltage power source to provide an output voltage Vp sufficient to power the external electric load. It is therefore possible to provide a low voltage power source having an output voltage of less than 20 volts, preferably less than 10 volts, and more preferably less than 5 volts. Likewise, the external voltage Ve provided to be electric load is such that Ve is at least two times Vp, preferably at least ten times Vp, and more preferably at least 100 times Vp.

Hot fuel cells expand when in use, which causes problems when the cells are connected in series. Exotic materials have been proposed to limit this thermal expansion, so that fuel cells may be placed closely together. The present invention allows fuel cells to be connected in parallel, so that they do not need to be placed closely together, and thermal expansion does not cause problems.

It will be clear that the external load can be any load, or a combination of electric loads. For example, it may be a single light source, such as a light emitting diode, or it may be the combination of electric loads as may be present in a home or a building. A particularly attractive use of the apparatus of the present invention is connecting it to a power grid. This requires that the apparatus be connected to a converter for converting electric energy generated by the apparatus to an alternating current at a voltage compatible with that of the grid. This arrangement makes it possible to sell power to the grid when the apparatus produces more power than is needed for internal use, and to supplement the power with power from the grid at times that the demand is greater than the amount of power produced by the apparatus.

Thus, the invention has been described by reference to certain embodiments discussed above. It will be recognized that these embodiments are susceptible to various modifications and alternative forms well known to those of skill in the art.

What is claimed is:

1. Apparatus for powering an electric load with a low-voltage power source, said apparatus comprising:
a) a low-voltage power source providing an output voltage Vp;
b) a first accumulator of electric energy, connected in series with the low-voltage power source and operating at a first voltage V1;
c) a second accumulator of electric energy, connected in parallel to the first accumulator, and operating at a second voltage V2;
wherein V1+Vp=V2.

2. The apparatus of claim 1 further comprising a first controller for optimizing the operation of the low-voltage power source.

3. The apparatus of claim 1 further comprising a third accumulator of electric energy, and a second controller for diverting electric energy to said third accumulator in response to an imbalance in availability of and demand for electric energy.

4. The apparatus of claim 3 wherein the second controller is integrated with the first controller.

5. The apparatus of claim 2 further comprising a third accumulator of electric energy, and a second controller for diverting electric energy to said third accumulator in response to an imbalance in availability of and demand for electric energy.

6. The apparatus of claim 5 wherein the second controller is integrated with the first controller.

7. The apparatus of claim 1 wherein the first accumulator and the second accumulator are selected from a group of accumulators consisting of chemical batteries, lead sulfate batteries, capacitors, super capacitors and fly wheels.

8. The apparatus of claim 1 wherein the low voltage power source comprises a photovoltaic cell, a thermovoltaic cell, or a fuel cell.

9. The apparatus of claim 1 wherein the low voltage power source comprises a plurality of photovoltaic cells grouped in a matrix of parallel-connected units.

10. The apparatus of claim 9 wherein said units are connected in parallel to each other as a result of being conductively mounted on a unitary sheet of conducting material.

11. The apparatus of claim 10 wherein the unitary sheet of conducting material is made of a metal.

12. The apparatus of claim 11 wherein the metal is selected from copper, nickel, aluminum, gold, and alloys thereof.

13. The apparatus of claim 10 wherein the sheet of conducting material is thermally connected to a cooling medium.

14. The apparatus of claim 13 wherein, when the apparatus is in use, the cooling medium absorbs heat generated in the photovoltaic cells, and transports the heat away from the photovoltaic cells.

15. The apparatus of claim 9 wherein the low voltage power source contains fewer than two bypass diodes for every 10 photovoltaic cells.

16. The apparatus of claim 9 wherein the low voltage power source comprises at least one photovoltaic cell having a surface area of more than 400 cm².

17. The apparatus of claim 1 wherein Vp is less than 20 Volts.

18. The apparatus of claim 1 providing an external voltage to the load of Ve, wherein Ve is at least 2×Vp.

19. The apparatus of claim 1 further comprising a converter for converting electric energy generated by the apparatus to an alternating current.

20. The apparatus of claim 19 which is connected to a power grid.
